(19) United States
(12) Patent Application Publication
(10) Pub. No.: US 2013/0256683 A1
(43) Pub. Date: Oct. 3, 2013

(54) COMPOUND SEMICONDUCTOR AND METHOD OF MANUFACTURING THE SAME

(71) Applicant: FUJITSU LIMITED, Kawasaki-shi (JP)

(72) Inventor: Kenji IMANISHI, Atsugi (JP)

(73) Assignee: FUJITSU LIMITED, Kawasaki-shi (JP)

(21) Appl. No.: 13/723,527

(22) Filed: Dec. 21, 2012

(30) Foreign Application Priority Data
Mar. 28, 2012 (JP) 2012-075037

(51) Int. Cl. H01L 29/778; H01L 29/66; H01L 29/20

(52) U.S. Cl. CPC H01L 29/778; H01L 29/2003; H01L 29/66431
USPC 257/76; 257/194; 438/172

(57) ABSTRACT

An embodiment of a compound semiconductor device includes: a substrate; an electron transport layer and an electron supply layer formed over the substrate; a gate electrode, a source electrode and a drain electrode formed over the electron supply layer; a p-type semiconductor layer formed between the electron supply layer and the gate electrode; and a hole canceling layer formed between the electron supply layer and the p-type semiconductor layer, the hole canceling layer containing a donor or a recombination center and canceling a hole.

### CROSS-REFERENCE TO RELATED APPLICATION

This application is based upon and claims the benefit of priority of the prior Japanese Patent Application No. 2012-075037, filed on Mar. 28, 2012, the entire contents of which are incorporated herein by reference.

### FIELD

The embodiments discussed herein are related to a compound semiconductor device and a method of manufacturing the same.

### BACKGROUND

In recent years, there has been vigorous development of electronic devices (compound semiconductor devices) having a GaN layer and an AlGaN layer sequentially formed over a substrate, wherein the GaN layer is used as an electron transport layer. One of the compound semiconductor device is known as a GaN-based high electron mobility transistor (HEMT). The GaN-based HEMT makes a wise use of a high density two-dimensional gas (2DEG) which generates at the heterojunction interface between AlGaN and GaN.

The band gap of GaN is 3.4 eV, which is larger than the band gap of Si (1.1 eV) and the band gap of GaAs (1.4 eV). In other words, GaN has a high breakdown field strength. GaN also has a high saturation electron velocity. GaN is, therefore, a material of great promise for compound semiconductor devices operable under high voltage and capable of yielding large output. The GaN-based HEMT is therefore expected as high-efficiency switching devices, and high-breakdown-voltage power devices for electric vehicles, and so forth.

Most of the GaN-based HEMTs, which utilize the high density two-dimensional gas, perform normally-on operation. In short, a current may flow, even when the gate voltage is off. The reason is that a lot of electrons exist in the channel. On the other hand, normally-off operation is important for a GaN-based HEMT for high-breakdown-voltage power devices in view of a fail-safe.

Investigations into various techniques have therefore been directed to achieve a GaN-based HEMT capable of normally-off operation. For example, there is a structure in which a p-type GaN layer containing p-type impurity such as Mg is formed between the gate electrode and the activated region.

However, a leakage current is likely to flow in the prior GaN-based HEMT provided with a p-type semiconductor layer.

[Patent Literature 1] Japanese Laid-Open Patent Publication No. 2004-273486

[Non-Patent Literature 1] Panasonic Technical Journal Vol. 55, No. 2, (2009)

### SUMMARY

According to an aspect of the embodiments, a compound semiconductor device includes: a substrate; an electron transport layer and an electron supply layer formed over the substrate; a gate electrode, a source electrode and a drain electrode formed over the electron supply layer; a p-type semiconductor layer formed between the electron supply layer and the gate electrode; and a hole canceling layer formed between the electron supply layer and the p-type semiconductor layer, the hole canceling layer containing a donor or a recombination center and canceling a hole.

According to another aspect of the embodiments, a method of manufacturing a compound semiconductor device includes: forming an electron transport layer and an electron supply layer over a substrate; forming a gate electrode, a source electrode and a drain electrode over the electron supply layer; forming a p-type semiconductor layer which is located between the electron supply layer and the gate electrode, before the forming the gate electrode; and forming a hole canceling layer which is located between the electron supply layer and the p-type semiconductor layer, before the forming the p-type semiconductor layer, the hole canceling layer containing a donor or a recombination center and canceling a hole.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a cross sectional view illustrating a structure of a compound semiconductor device according to a first embodiment;

FIG. 1B is a diagram illustrating a band structure of the compound semiconductor device according to the first embodiment;

FIG. 2A is a cross sectional view illustrating a structure of a referential example;

FIG. 2B is a diagram illustrating a band structure of the referential example;

FIG. 3A is a diagram illustrating a relation between a gate voltage and a drain current of the compound semiconductor device according to the first embodiment;

FIG. 3B is a diagram illustrating a relation between a gate voltage and a drain current of the referential example;

FIG. 4A is a diagram illustrating a relation between a drain voltage and a leakage current of the compound semiconductor device according to the first embodiment;

FIG. 4B is a diagram illustrating a relation between a drain voltage and a leakage current of the referential example;

FIGS. 5A to 5H are cross sectional views illustrating, in sequence, a method of manufacturing the compound semiconductor device according to the first embodiment;

FIG. 6A is a cross sectional view illustrating a structure of a compound semiconductor device according to a second embodiment;

FIG. 6B is a diagram illustrating a band structure of the compound semiconductor device according to the second embodiment;

FIG. 7A is a cross sectional view illustrating a structure of a compound semiconductor device according to a third embodiment;

FIG. 7B is a cross sectional view illustrating a structure of a compound semiconductor device according to a fourth embodiment;

FIGS. 8A to 8F are cross sectional views illustrating, in sequence, a method of manufacturing the compound semiconductor device according to the third embodiment;

FIG. 9A is a cross sectional view illustrating a structure of a compound semiconductor device according to a fifth embodiment;

FIG. 9B is a cross sectional view illustrating a structure of a compound semiconductor device according to a sixth embodiment;

FIG. 10 is a drawing illustrating a discrete package according to a seventh embodiment;

FIG. 11 is a wiring diagram illustrating a power factor correction (PFC) circuit according to an eighth sixth embodiment;

FIG. 12 is a wiring diagram illustrating a power supply apparatus according to a ninth embodiment;

FIG. 13 is a wiring diagram illustrating a high-frequency amplifier according to a tenth embodiment.

### DESCRIPTION OF EMBODIMENTS

The present inventor extensively investigated into the reasons why a leakage current is likely to flow, when the p-type semiconductor layer is provided, in prior arts. Then, it was found out that holes are generated in the vicinity of the lower surface of the p-type semiconductor layer as a high voltage is applied to the drain, and the holes induce electrons in the channel region where 2DEG has been canceled by the p-type semiconductor layer. The leakage flows due to the induced electrons. Moreover, that deteriorates the breakdown voltage characteristics. Then the present inventor got the idea to provide a hole canceling layer which may cancel and decrease holes in the vicinity of the lower surface of the p-type semiconductor layer.

Embodiments will be detailed below, referring to the attached drawings.

### First Embodiment

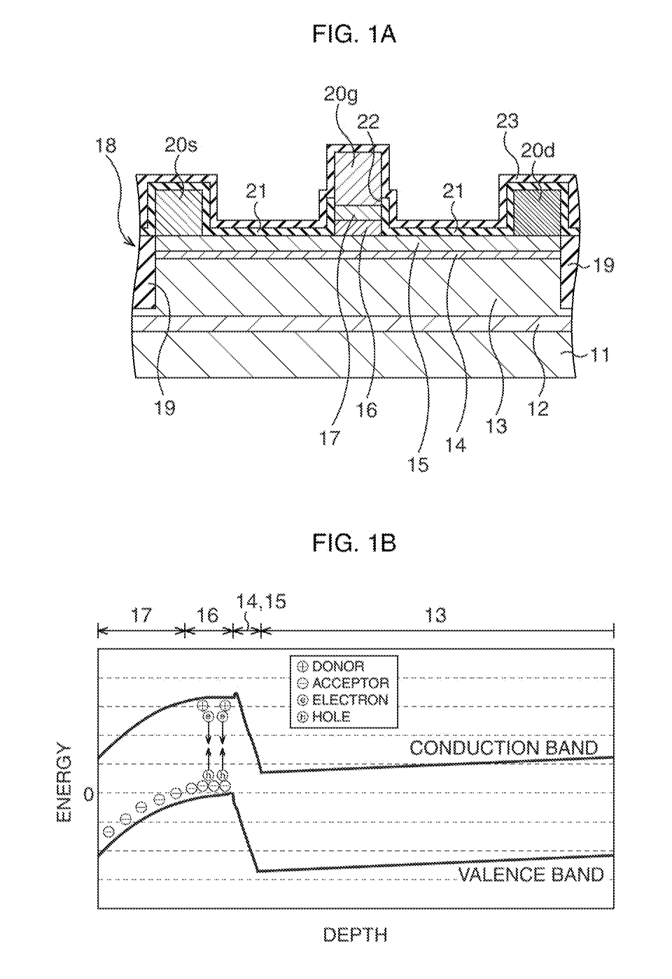

A first embodiment will be described. FIG. 1A is a cross sectional view illustrating a structure of a GaN-based HEMT (compound semiconductor device) according to the first embodiment, and FIG. 1B is a diagram illustrating a band structure of the GaN-based HEMT according to the first embodiment.

In the first embodiment, a compound semiconductor stacked structure 18 is formed over a substrate 11 such as Si substrate, as illustrated in FIG. 1A. The compound semiconductor stacked structure 18 includes a buffer layer 12, an electron transport layer 13, a spacer layer 14, an electron supply layer 15, a donor containing layer 16 and a cap layer 17. The buffer layer 12 may be an AlN layer and/or an AlGaN layer of approximately 10 nm to 2000 nm thick, for example. The electron transport layer 13 may be an i-GaN layer of approximately 1000 nm to 3000 nm thick, which is not intentionally doped with an impurity, for example. The spacer layer 14 may be an i-Al_{0.25}Ga_{0.75}N layer of approximately 5 nm thick, which is not intentionally doped with an impurity, for example. The electron supply layer 15 may be an n-type n-Al_{0.25}Ga_{0.75}N layer of approximately 30 nm thick, for example. The electron supply layer 15 may be doped with approximately 5×10¹⁸ cm⁻³ of Si as an n-type impurity, for example.

An element isolation region 19 which defines an element region is formed in the electron supply layer 15, the spacer layer 14, the electron transport layer 13 and the buffer layer 12. A source electrode 20s and a drain electrode 20d are formed over the electron supply layer 15 in the element region. The donor containing layer 16 and the cap layer 17 are formed over a portion of the electron supply layer 15 between the source electrode 20s and the drain electrode 20d in planar view. The cap layer 17 may be a p-type p-GaN layer of approximately 30 nm thick, for example. The cap layer 17 may be doped with approximately 5×10¹⁹ cm⁻³ of Mg as a p-type impurity, for example. The cap layer 17 may be an example of a p-type semiconductor layer. The donor containing layer 16 is between the cap layer 17 and the electron supply layer 17, and may be a p-type p-GaN layer of approximately 30 nm thick containing a donor along with a p-type impurity, for example. The donor containing layer 16 may be doped with approximately 5×10¹⁹ cm⁻³ of Mg as the p-type impurity similarly to the cap layer 17, for example, and further doped with approximately 1×10¹⁷ cm⁻³ of Si as the donor. The donor containing layer 16 may be an example of a hole canceling layer.

An insulating film 21 is formed over the electron supply layer 15 so as to cover the source electrode 20s and the drain electrode 20d. An opening 22 is formed in the insulating film 21 so as to expose the cap layer 17, and a gate electrode 20g is formed in the opening 22. An insulating film 23 is formed over the insulating film 21 so as to cover the gate electrode 20g. While materials used for the insulating films 21 and 23 are not specifically limited, a Si nitride film may be used, for example. The insulating films 21 and 23 are an example of a termination film.

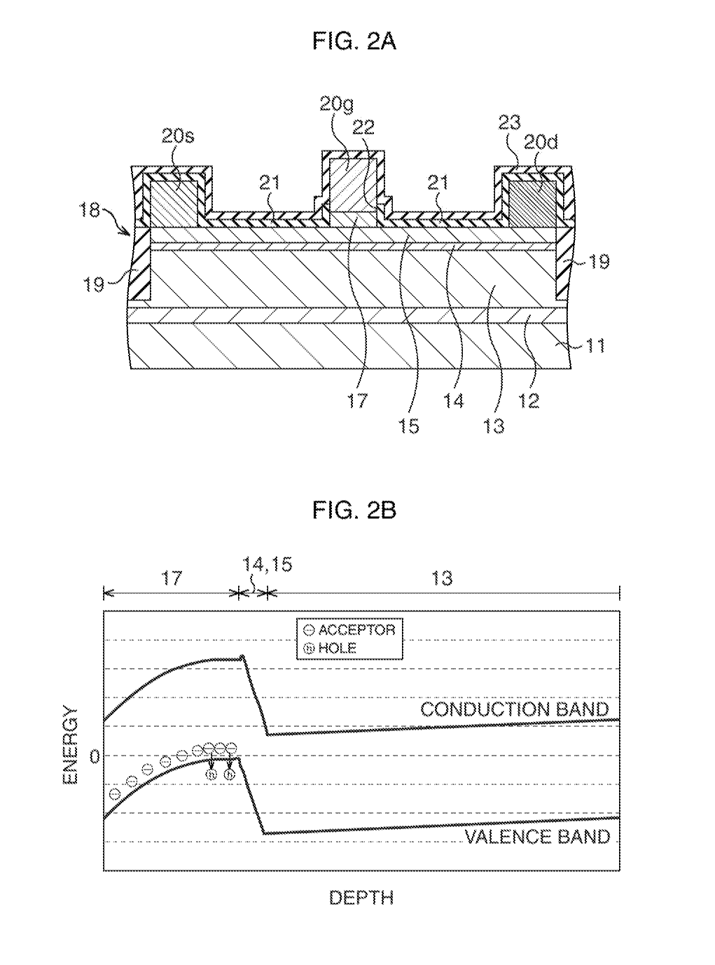

FIG. 1B is a diagram illustrating a band structure beneath the gate electrode 20g of the GaN-based HEMT thus configured. FIG. 2B is a diagram illustrating a band structure of a referential example illustrated in FIG. 2A, in which the donor containing layer 16 is not provided. As illustrated in FIG. 2B, an acceptor in the cap layer 17 emits holes at a certain rate (activation efficiency) in the referential example, in which the donor containing layer 16 is not provided. The emitted holes are generated in a valence band. On the other hand, as illustrated in FIG. 1B, in the first embodiment, holes are emitted from an acceptor in the donor containing layer 16 and the cap layer 17, but the holes are recombined with electrons emitted from the donor in the donor containing layer 16 and disappear. Accordingly, the holes which may be generated in a valence band are extremely decreased, and in some cases, the holes are not generated at all. Therefore, it is drastically suppressed to induce electrons in the channel region due to the generation of holes, and the leakage current also can be drastically suppressed. Moreover, that improves the breakdown voltage characteristics.

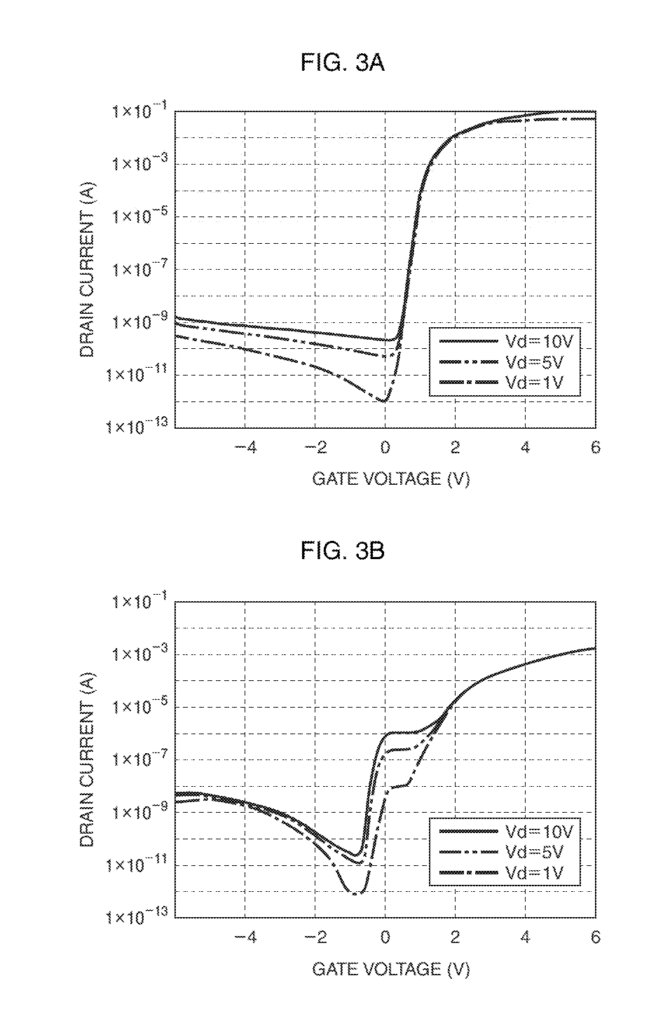

FIG. 3A and FIG. 3B are diagrams each illustrating a relation between a gate voltages and a drain current at various drain voltages. FIG. 3A illustrates the relation of the first embodiment, and FIG. 3B illustrates the relation of the referential example illustrated in FIG. 2A. As obvious from the comparison between FIG. 3A and FIG. 3B, a larger drain current flows in the referential example than in the first embodiment, even in a case where the gate voltage is 0V. Besides, an abrupt increase of the drain current, which is called “hump”, is observed at a low gate voltage range in the referential example. The hump is remarkable as the drain voltage Vd is high. On the other hand, the hump is not observed even in a high drain voltage Vd range in the first embodiment. The drain current at the gate voltage of 1V largely varies in the referential example, although that is substantially constant in the first embodiment. Therefore, ON/OFF can be correctly discriminated from each other when a threshold is set at the gate voltage of 1V in the first embodiment, but it is difficult correctly discriminate ON/OFF from each other when a threshold is set at the gate voltage of 1V in the referential example, and that may induce malfunction.

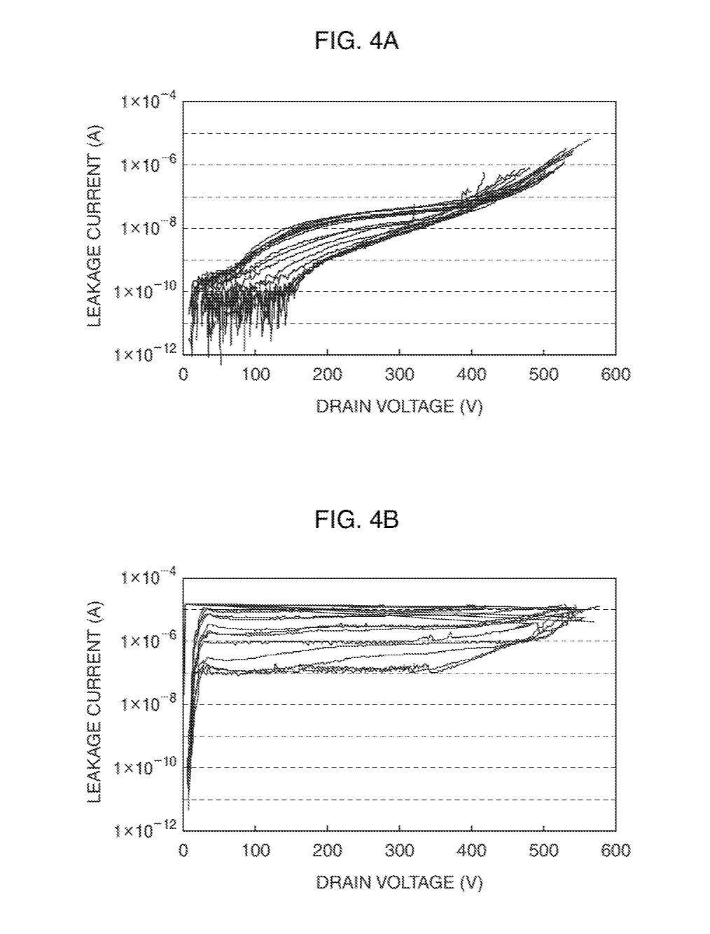

FIG. 4A and FIG. 4B are diagrams each illustrating a relation between a drain voltages and a leakage current at the gate voltage of 0V. FIG. 4A illustrates the relation of the first embodiment, and FIG. 4B illustrates the relation of the referential example illustrated in FIG. 2A. A large leakage flows even at an extremely low drain voltage in the referential example as illustrated in FIG. 4B, although increase of a leakage current as increase of a drain voltage is gradual in the first embodiment as illustrated in FIG. 4A. Incidentally, graphs in each of FIG. 4A and FIG. 4B illustrate plural results of GaN-based HEMTs, which were manufactured in one substrate (wafer).

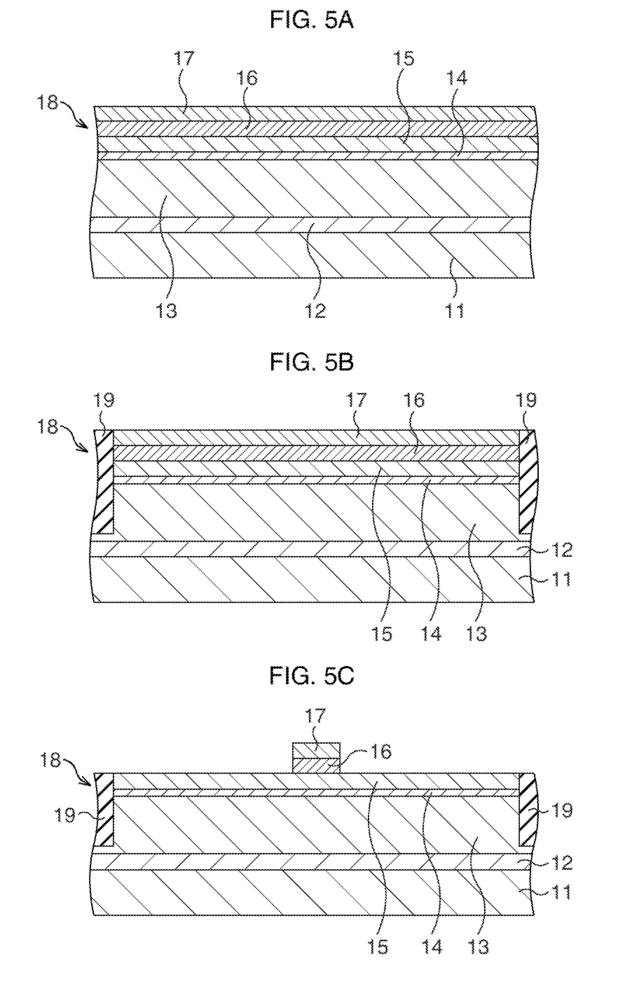

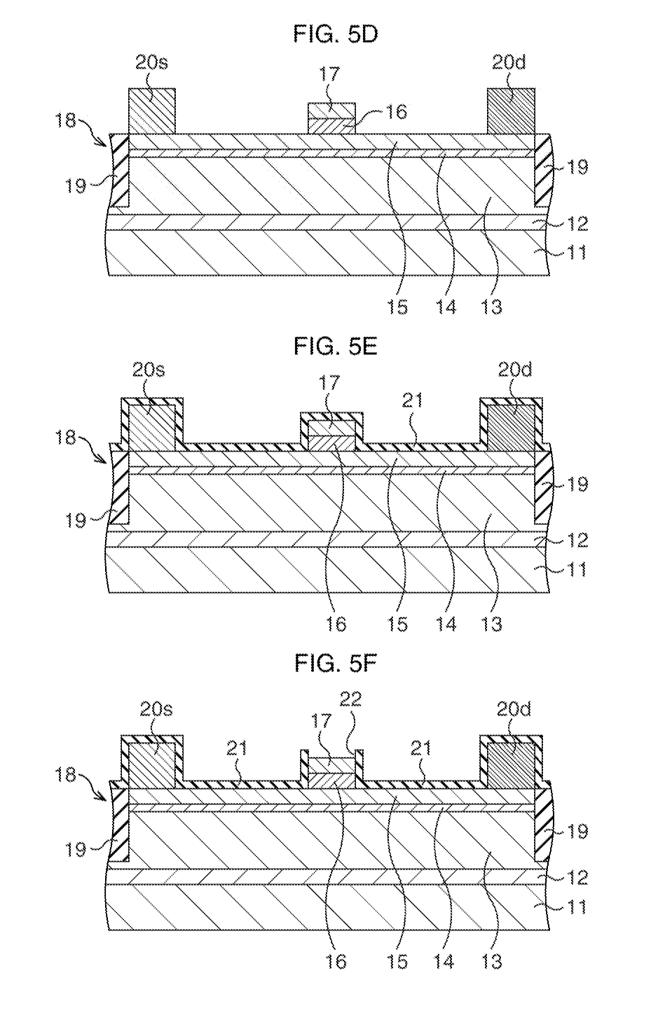

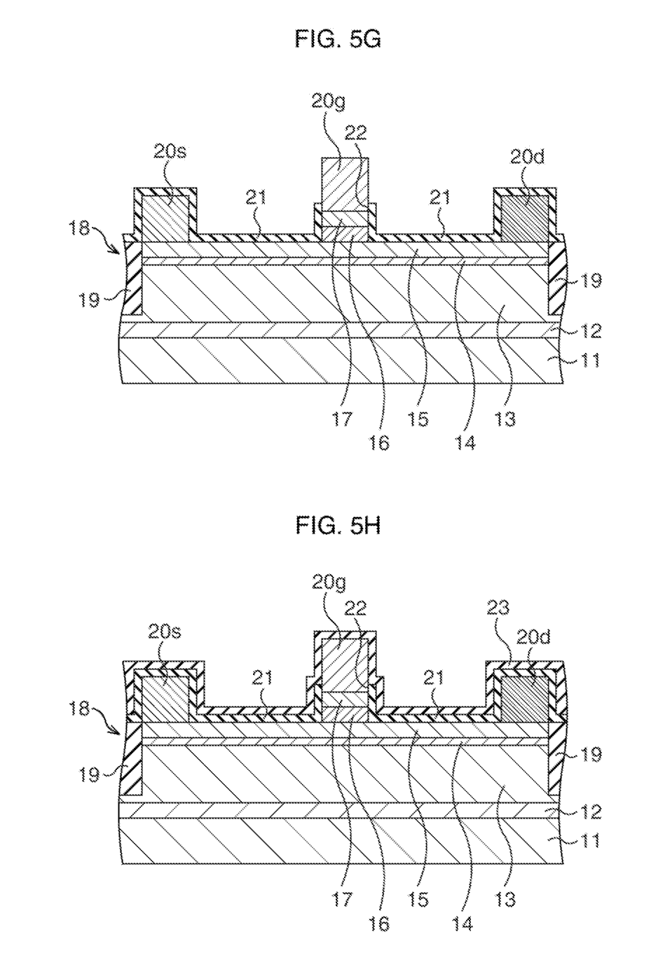

Next, a method of manufacturing the GaN-based HEMI (compound semiconductor device) according to the first embodiment will be explained. FIG. 5A to FIG. 5H are cross sectional views illustrating, in sequence, a method of manufacturing the GaN-based HEMI (compound semiconductor device) according to the first embodiment.

First, as illustrated in FIG. 5A, the buffer layer 12, the electron transport layer 13, the spacer layer 14, the electron supply layer 15, the donor containing layer 16 and the cap layer 17 may be formed over the substrate 11 by a crystal growth process such as metal organic vapor phase epitaxy (MOVPE) and molecular beam epitaxy (MBE). In the process of forming the AlN layer, the AlGaN layer and the GaN layer by MOVPE, a mixed gas of trimethylaluminum (TMA) gas as an Al source, trimethylgallium (TMG) gas as a Ga source, and ammonia (NH₃) gas as a N source, may be used. In the process, on/off of supply and flow rates of trimethylaluminum gas and trimethylgallium gas are appropriately set, depending on compositions of the compound semiconductor layers to be grown. Flow rate of ammonia gas, which is common to all compound semiconductor layers, may be set to approximately 100 sccm to 100 SLM. Growth pressure may be adjusted to approximately 50 Torr to 300 Torr, and growth temperature may be adjusted to approximately 1000° C. to 1200° C., for example. In the process of growing the n-type compound semiconductor layers, Si may be doped into the compound semiconductor layers by adding SiH₄ gas, which contains Si, to the mixed gas at a predetermined flow rate, for example. Dose of Si may be adjusted to approximately 1×10¹⁸ cm⁻³ to 1×10²⁰ cm⁻³, and to 5×10¹⁸ cm⁻³ or around, for example. Dose of Mg into the donor containing layer 16 and the cap layer 17 may be adjusted to approximately 1×10¹⁹ cm⁻³ to 1×10²⁰ cm⁻³, and to 5×10¹⁹ cm⁻³ or around, for example. Dose of Si into the donor containing layer 16 may be adjusted to approximately 1×10¹⁶ cm⁻³ to 1×10¹⁸ cm⁻³, and to 1×10¹⁷ cm⁻³ or around, for example. After forming the cap layer 17, Mg being a p-type impurity is activated by annealing. The compound semiconductor structure 18 is thus configured.

Then, the element isolation region 19, which defines the element region, is formed in the compound semiconductor stacked structure 18, as illustrated in FIG. 5B. In the process of forming the element isolation region 19, for example, a photoresist pattern is formed over the cap layer 17 so as to selectively expose region where the element isolation region 19 is to be formed, and ion such as Ar ion is implanted through the photoresist pattern used as a mask. Alternatively, dry etching may be performed with a chlorine-containing gas, through the photoresist pattern used as an etching mask.

Thereafter, the cap layer 17 and the donor containing layer 16 are etched so as to remain in a region where the gate electrode is to be formed, as illustrated in FIG. 5C. In the process of patterning the cap layer 17 and the donor containing layer 16, for example, a photoresist pattern is formed over the cap layer 17 so as to cover the region where the cap layer 17 and the donor containing layer 16 is to be remained, and dry etching is performed with a chlorine-containing gas, through the photoresist pattern used as an etching mask.

Subsequently, the source electrode 20s and the drain electrode 20d are formed over the electron supply layer 15 so as to make the remained cap layer 17 and the remained donor containing layer 16 be between the source electrode 20s and the drain electrode 20d in the element region, as illustrated in FIG. 5D. The source electrode 20s and the drain electrode 20d may be formed by a lift-off process, for example. More specifically, a photoresist pattern is formed so as to expose regions where the source electrode 20s and the drain electrode 20d are to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ta film of approximately 20 nm thick may be formed, and an Al film of approximately 200 nm thick may be then formed. The metal film is then annealed, for example, in a nitrogen atmosphere at 400° C. to 1000° C. (at 550° C., for example) to thereby ensure the ohmic characteristic.

Then, the insulating film 21 is formed over the entire surface, as illustrated in FIG. 5E. The insulating film 21 is preferably formed by atomic layer deposition (ALD), plasma-assisted chemical vapor deposition (CVD), or sputtering.

Thereafter, the opening 22 is formed in the insulating film 21 so as to expose the cap layer 17 at a position between the source electrode 20s and the drain electrode 20d in planar view, as illustrated in FIG. 5F.

Subsequently, the gate electrode 20g is formed in the opening 22, as illustrated in FIG. 5G. The gate electrode 20g may be formed by a lift-off process, for example. More specifically, a photoresist pattern is formed so as to expose a region where the gate electrode 20g is to be formed, a metal film is formed over the entire surface by an evaporation process while using the photoresist pattern as a growth mask, for example, and the photoresist pattern is then removed together with the portion of the metal film deposited thereon. In the process of forming the metal film, for example, a Ni film of approximately 30 nm thick may be formed, and a Au film of approximately 400 nm thick may be then formed. Thereafter, the insulating film 23 is formed over the insulating film 21 so as to cover the gate electrode 20g, as illustrated in FIG. 5H.

The GaN-based HEMT according to the first embodiment may be thus manufactured.

### Second Embodiment

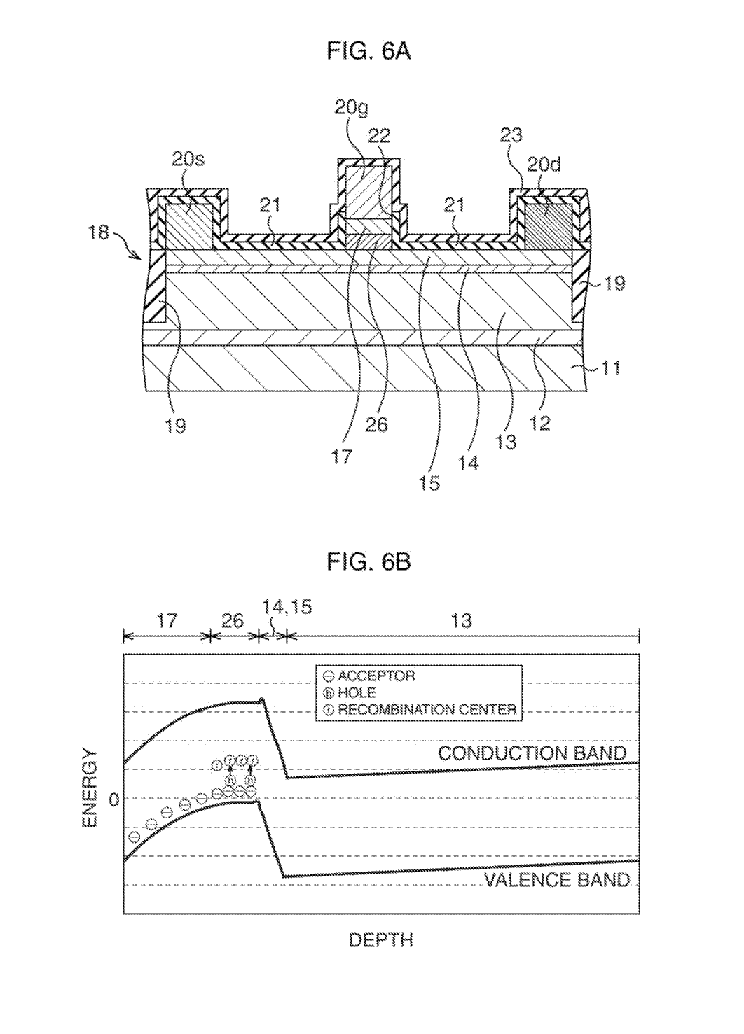

Next, a second embodiment will be explained. FIG. 6A is a cross sectional view illustrating a structure of a GaN-based HEMT (compound semiconductor device) according to the second embodiment, and FIG. 6B is a diagram illustrating a band structure of the GaN-based HEMT according to the second embodiment.

In the second embodiment, a recombination center containing layer 26 is formed instead of the donor containing layer 16 in the first embodiment. The recombination center containing layer 26 is between the cap layer 17 and the electron supply layer 15, and may be a p-type p-GaN layer of approximately 30 nm thick containing a recombination center along with a p-type impurity, for example. The recombination center containing layer 26 may be doped with approximately 5×10¹⁹ cm⁻³ of Mg as the p-type impurity similarly to the cap layer 17, for example, and further doped with approximately 1×10¹⁸ cm⁻³ of Fe as the recombination center. The recombination center containing layer 26 may be an example of a hole canceling layer. The other structure is similar to the first embodiment.

FIG. 6B is a diagram illustrating a band structure beneath the gate electrode 20g of the GaN-based HEMT thus configured. As illustrated in FIG. 6B, in the second embodiment, holes are emitted from an acceptor in the recombination center containing layer 26 and the cap layer 17, but the holes disappear due to capture or recombination by the recombination center in the recombination center containing layer 26. Accordingly, the holes which may be generated in a valence band are extremely decreased, and in some cases, the holes are not generated at all. Therefore, it is drastically suppressed to induce electrons in the channel region due to the generation of holes, and the leakage current also can be drastically suppressed. Moreover, that improves the breakdown voltage characteristics.

Cr, Co, Ni, Ti, V and Sc are also examples of elements capable of being used as the recombination center other than Fe. The recombination center containing layer 26 may contain one or more kinds of these elements.

### Third Embodiment

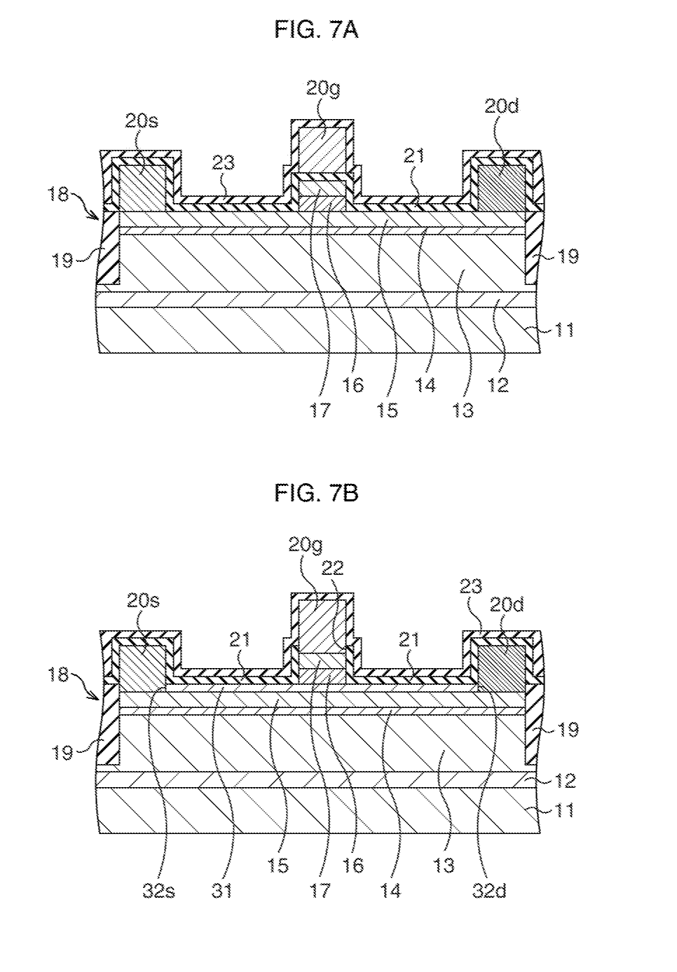

Next, a third embodiment will be explained. FIG. 7A is a cross sectional view illustrating a structure of a compound semiconductor device according to the third embodiment.

In contrast to the first embodiment, having the gate electrode 20g brought into Schottky contact with the compound semiconductor stacked structure 18, the third embodiment adopts the insulating film 21 between the gate electrode 20g and the cap layer 17, so as to allow the insulating film 21 to function as a gate insulating film. In short, the opening 22 is not formed in the insulating film 21, and a MIS-type structure is adopted. The other structure is similar to the first embodiment.

Also the third embodiment thus configured successfully achieves, similarly to the first embodiment, the effects of suppressing the leakage current and improving the breakdown voltage characteristics, with the presence of the donor containing layer 16.

A material for the insulating film 21 is not specifically limited, wherein the preferable examples include oxide, nitride or oxynitride of Si, Al, Hf, Zr, Ti, Ta and W. Aluminum oxide is particularly preferable. Thickness of the insulating film 21 may be 2 nm to 200 nm, and 10 nm or around, for example.

### Fourth Embodiment

Next, a fourth embodiment will be explained. FIG. 7B is a cross sectional view illustrating a structure of a compound semiconductor device according to the fourth embodiment.

In the fourth embodiment, a hole barrier layer 31 is formed over the electron supply layer 15, and the donor containing layer 16, the cap layer 17 and the gate electrode 20g are formed over the hole barrier layer 31, as illustrated in FIG. 7B. The insulating film 21 and the insulating film 23 are also formed over the hole barrier layer 31. A recess 32s for a source electrode and a recess 32d for a drain electrode are formed in the hole barrier layer 31, the source electrode 20s is formed over the electron supply layer 15 through the recess 32s, and the drain electrode 20d is formed over the electron supply layer 15 through the recess 32d. The hole barrier layer 31 may be an AlN layer of approximately 2 nm thick. The recesses 32s and 32d may be omitted, and the hole barrier layer 31 may remain between the electron supply layer 15, and the source electrode 20s and the drain electrode 20d. A contact resistance is lower and the property is better when the source electrode 20s and the drain electrode 20d are in direct contact with the electron supply layer 15. The other structure is similar to the first embodiment.

Holes are not likely to diffuse from the p-type cap layer 17 into the channel including 2DEG even when an on-voltage is applied to the gate electrode 20g, since the hole barrier layer 31 is provided in the fourth embodiment, although holes may diffuse into the channel in some cases when an on-voltage is applied to the gate electrode 20g in the first embodiment. Therefore, increase of on-resistance and variation of current path due to the diffusion of holes are suppressed, and further better characteristics can be obtained in the fourth embodiment. For example, more stable drain current can be obtained.

When a lattice constant of a nitride semiconductor of the hole barrier layer 31 is smaller than that or the electron supply layer 15, the density of 2DEG in the vicinity of the electron transport layer 13 is higher and on-resistance is much lower.

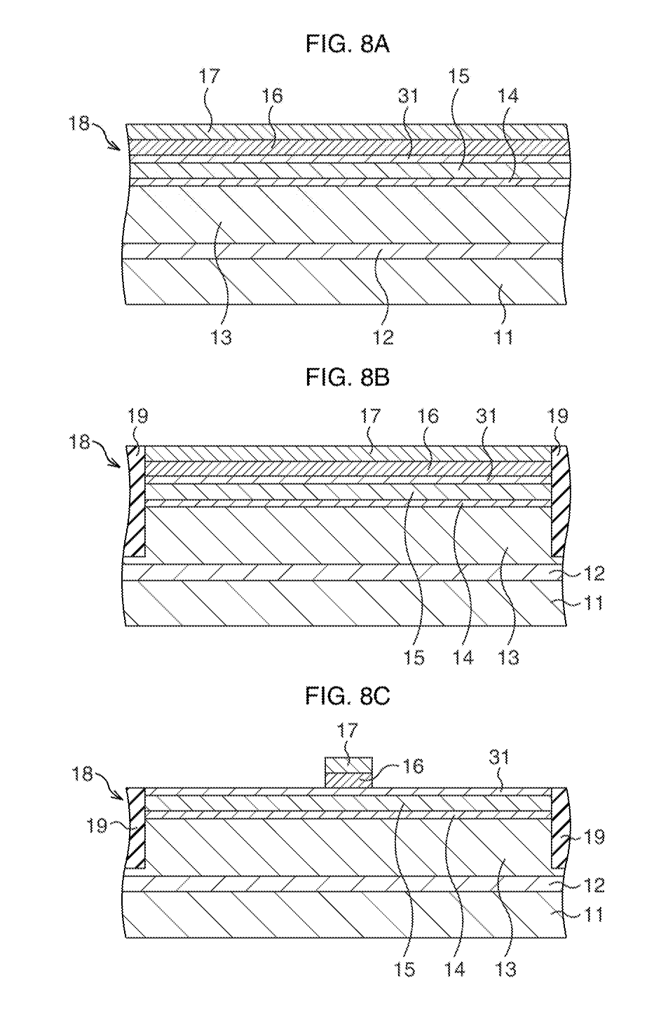

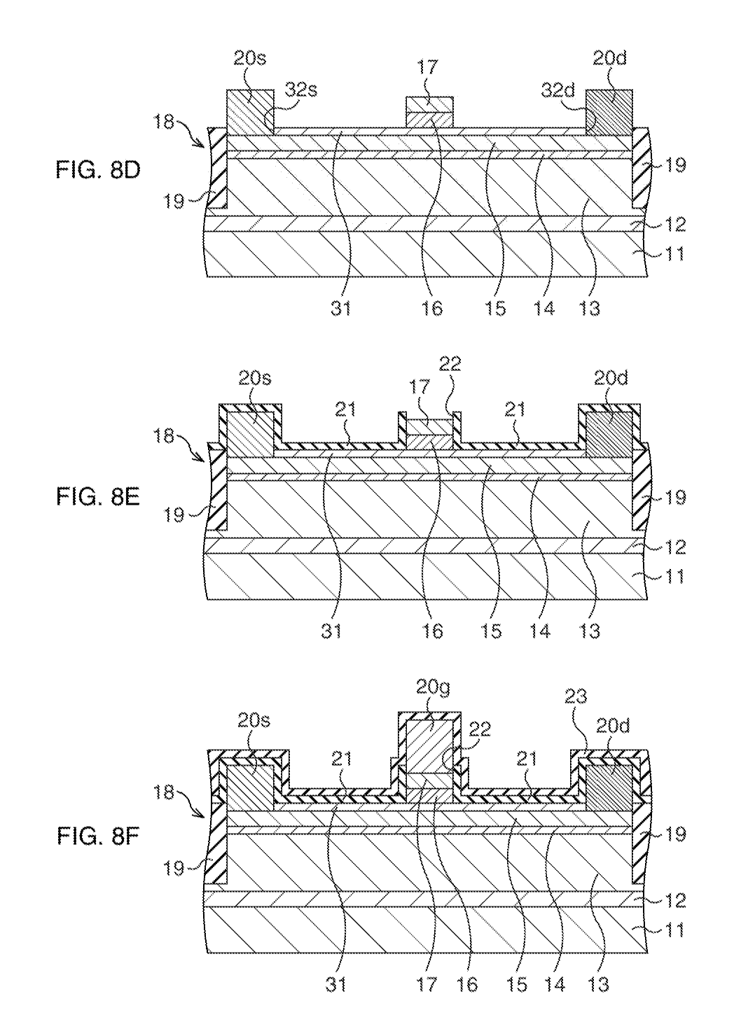

Next, a method of manufacturing the GaN-based HEMT (compound semiconductor device) according to the fourth embodiment will be explained. FIG. 8A to FIG. 8F are cross sectional views illustrating, in sequence, a method of manufacturing the GaN-based HEMT (compound semiconductor device) according to the fourth embodiment.

First, as illustrated in FIG. 8A, the buffer layer 12, the electron transport layer 13, the spacer layer 14, the electron supply layer 15, the hole barrier layer 31, the donor containing layer 16 and the cap layer 17 may be formed over the substrate 11 by a crystal growth process such as MOVPE and MBE. The hole barrier layer 31 may be formed continuously with the electron supply layer 15 and so on. In this case, for example, supplying the TMG gas and the SiH₄ gas for forming the electron supply layer 15 is suspended, while supplying the TMA gas and the NH₃ gas is maintained. After forming the cap layer 17, annealing is performed to activate Mg being a p-type impurity. The hole barrier layer 31 also may be included in the compound semiconductor stacked structure 18. Then, the element isolation region 19, which defines the element region, is formed in the compound semiconductor stacked structure 18 as illustrated in FIG. 8B, similarly to the first embodiment. Thereafter, as illustrated in FIG. 8C, the cap layer 17 and the donor containing layer 16 are patterned so as to remain in a region where the gate electrode is to be formed, similarly to the first embodiment.

Subsequently, as illustrated in FIG. 8D, the recesses 32s and 32d are formed in the hole barrier layer 31 in the element region. In the process of forming the recesses 32s and 32d, for example, a photoresist pattern is formed over the compound semiconductor stacked structure 18 so as to expose regions where the recesses 32s and 32d are to be formed, and dry etching is performed with a chlorine-containing gas, through the photoresist pattern used as an etching mask. Subsequently, the source electrode 20s is formed in the recess 32s, and the drain electrode 20d is formed in the recess 32d. Then, annealing is performed, for example, in a nitrogen atmosphere at 400° C. to 1000° C. (at 550° C., for example) to thereby ensure the ohmic characteristic. Thereafter, the insulating film 21 is formed over the entire surface, and the opening 22 is formed in the insulating film 21 so as to expose the cap layer 17 at a position between the source electrode 20s and the drain electrode 20d in planar view, as illustrated in FIG. 8E. Subsequently, as illustrated in FIG. 8F, the gate electrode 20g is formed in the opening 22, and the insulating film 23 is formed over the insulating film 21 so as to cover the gate electrode 20g, similarly to the first embodiment.

The GaN-based HEMT according to the fourth embodiment may be thus manufactured.

Note that etching selectivity relating to dry etching between GaN of the cap layer 17 and the donor containing layer 16 and AlGaN of the hole barrier layer 31 is large. Thus, as for etching the cap layer 17 and the donor containing layer 16, it becomes abruptly difficult for the etching to progress once a surface of the hole barrier layer 31 appears. In other words, the dry etching with the hole barrier layer 31 used as an etching stopper is capable. Accordingly, the dry etching may be easily controlled.

Besides, though some Mg may diffuse into the channel during the annealing to activate Mg as a p-type impurity in the first embodiment, the diffusion can be suppressed in the fourth embodiment.

Note that the hole barrier layer 31 is not specifically limited to an AlN layer if the band gap of the hole barrier layer 31 is larger than that of the electron supply layer 15, and an AlGaN layer whose Al fraction is higher than that of the electron supply layer 15 may be used for the hole barrier layer 31, for example. Alternatively, an InAlN layer may be used for the hole barrier layer 31, for example. When an AlGaN layer is used for the hole barrier layer 31, composition of the hole barrier layer 31 may be represented by Al_{y}Ga_{1-y}N (x<y<1), with composition of the electron supply layer 15 being represented by AlₓGa₁₋ₓN (0<x<1). When an InAlN layer is used for the hole barrier layer 31, composition of the hole barrier layer 31 may be represented by In_{z}Ai_{1-z}N (0≦z≦1), with composition of the electron supply layer 15 being represented by AlₓGa₁₋ₓN (0<x<1). A thickness of the hole barrier layer 31 is preferably 1 nm or more and 3 nm or less (2 nm, for example) if the hole barrier layer 31 is an AlN layer, and preferably 3 nm or more and 8 nm or less (5 nm, for example) if the hole barrier layer 31 is an AlGaN layer or InAlN layer. When the hole barrier layer 31 is thinner than the lower limit of the above-described preferable range, the hole barrier property may be low. When the hole barrier layer 31 is thicker than the upper limit of the above-described preferable range, the normally-off operation may be relatively difficult. Moreover, as described above, when a lattice constant of a nitride semiconductor of the hole barrier layer 31 is smaller than that or the electron supply layer 15, the density of 2DEG in the vicinity of the electron transport layer 13 may be higher and on-resistance may be lower.

### Fifth Embodiment

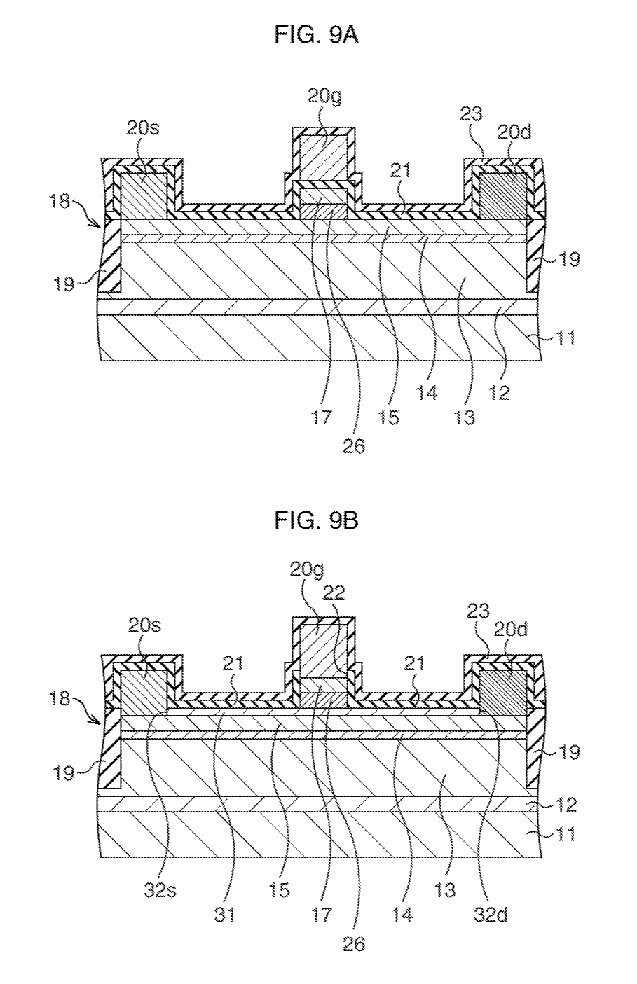

Next, a fifth embodiment will be explained. FIG. 9A is a cross sectional view illustrating a structure of a compound semiconductor device according to the fifth embodiment.

In contrast to the second embodiment, having the gate electrode 20g brought into Schottky contact with the compound semiconductor stacked structure 18, the fifth embodiment adopts the insulating film 21 between the gate electrode 20g and the cap layer 17, so as to allow the insulating film 21 to function as a gate insulating film, similarly to the third embodiment. In short, the opening 22 is not formed in the insulating film 21, and a MIS-type structure is adopted. The other structure is similar to the second embodiment.

Also the fifth embodiment thus configured successfully achieves, similarly to the second embodiment, the effects of suppressing the leakage current and improving the breakdown voltage characteristics, with the presence of the recombination center containing layer 26.

### Sixth Embodiment

Next, a sixth embodiment will be explained. FIG. 9B is a cross sectional view illustrating a structure of a compound semiconductor device according to the sixth embodiment.

In the sixth embodiment, the hole barrier layer 31 is formed over the electron supply layer 15, and the recombination center containing layer 26, the cap layer 17 and the gate electrode 20g are formed over the hole barrier layer 31, as illustrated in FIG. 9B. The insulating film 21 and the insulating film 23 are also formed over the hole barrier layer 31. The recess 32s for a source electrode and the recess 32d for a drain electrode are formed in the hole barrier layer 31, the source electrode 20s is formed over the electron supply layer 15 through the recess 32s, and the drain electrode 20d is formed over the electron supply layer 15 through the recess 32d. The hole barrier layer 31 may be an AlN layer of approximately 2 nm thick. The recesses 32s and 32d may be omitted, and the hole barrier layer 31 may remain between the electron supply layer 15, and the source electrode 20s and the drain electrode 20d. A contact resistance is lower and the property is better when the source electrode 20s and the drain electrode 20d are in direct contact with the electron supply layer 15. The other structure is similar to the second embodiment.

Also the sixth embodiment thus configured successfully achieves, similarly to the second embodiment, the effects of suppressing the leakage current and improving the breakdown voltage characteristics, with the presence of the recombination center containing layer 26. Moreover, further better characteristics can be obtained due to suppressing the diffusion of holes, similarly to the fourth embodiment. As for manufacturing method of the sixth embodiment, effects such an easy control of etching can be obtained similarly to the fourth embodiment.

### Seventh Embodiment

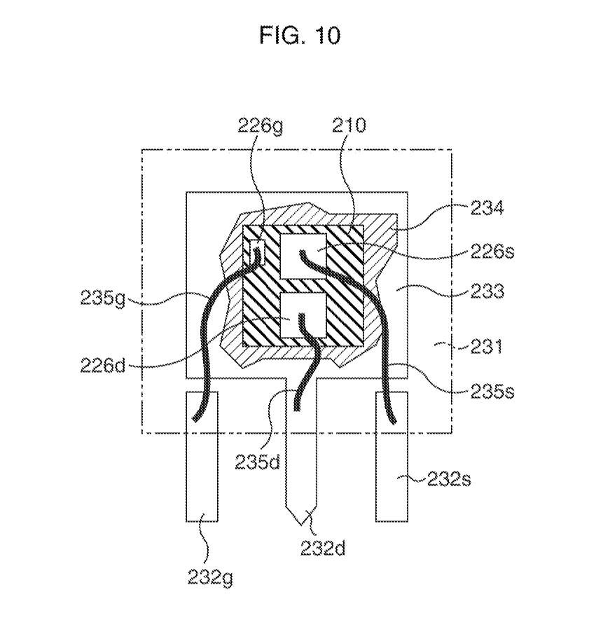

A seventh embodiment relates to a discrete package of a compound semiconductor device which includes a GaN-based HEMI. FIG. 10 is a drawing illustrating the discrete package according to the seventh embodiment.

In the seventh embodiment, as illustrated in FIG. 10, a back surface of a HEMT chip 210 of the compound semiconductor device according to any one of the first to sixth embodiments is fixed on a land (die pad) 233, using a die attaching agent 234 such as solder. One end of a wire 235d such as an A1 wire is bonded to a drain pad 226d, to which the drain electrode 20d is connected, and the other end of the wire 235d is bonded to a drain lead 232d integral with the land 233. One end of a wire 235s such as an A1 wire is bonded to a source pad 226s, to which the source electrode 20s is connected, and the other end of the wire 235s is bonded to a source lead 232s separated from the land 233. One end of a wire 235g such as an A1 wire is bonded to a gate pad 226g, to which the gate electrode 20g is connected, and the other end of the wire 235g is bonded to a gate lead 232g separated from the land 233. The land 233, the HEMT chip 210 and so forth are packaged with a molding resin 231, so as to project outwards a portion of the gate lead 232g, a portion of the drain lead 232d, and a portion of the source lead 232s.

The discrete package may be manufactured by the procedures below, for example. First, the HEMT chip 210 is bonded to the land 233 of a lead frame, using a die attaching agent 234 such as solder. Next, with the wires 235g, 235d and 235s, the gate pad 226g is connected to the gate lead 232g of the lead frame, the drain pad 226d is connected to the drain lead 232d of the lead frame, and the source pad 226s is connected to the source lead 232s of the lead frame, respectively, by wire bonding. The molding with the molding resin 231 is conducted by a transfer molding process. The lead frame is then cut away.

### Eighth Embodiment

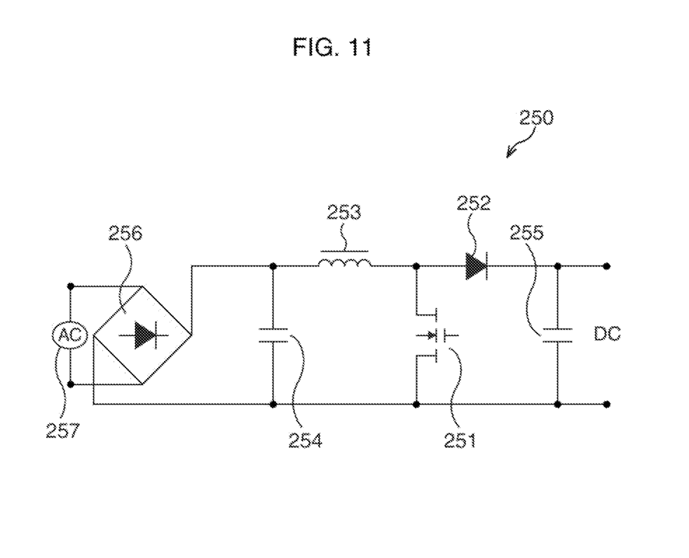

Next, an eighth embodiment will be explained. The eighth embodiment relates to a PFC (power factor correction) circuit equipped with a compound semiconductor device which includes a GaN-based HEMT. FIG. 11 is a wiring diagram illustrating the PFC circuit according to the eighth embodiment.

The PFC circuit 250 has a switching element (transistor) 251, a diode 252, a choke coil 253, capacitors 254 and 255, a diode bridge 256, and an AC power source (AC) 257. The drain electrode of the switching element 251, the anode terminal of the diode 252, and one terminal of the choke coil 253 are connected with each other. The source electrode of the switching element 251, one terminal of the capacitor 254, and one terminal of the capacitor 255 are connected with each other. The other terminal of the capacitor 254 and the other terminal of the choke coil 253 are connected with each other. The other terminal of the capacitor 255 and the cathode terminal of the diode 252 are connected with each other. A gate driver is connected to the gate electrode of the switching element 251. The AC 257 is connected between both terminals of the capacitor 254 via the diode bridge 256. A DC power source (DC) is connected between both terminals of the capacitor 255. In the embodiment, the compound semiconductor device according to any one of the first to sixth embodiments is used as the switching element 251.

In the process of manufacturing the PFC circuit 250, for example, the switching element 251 is connected to the diode 252, the choke coil 253 and so forth with solder, for example.

### Ninth Embodiment

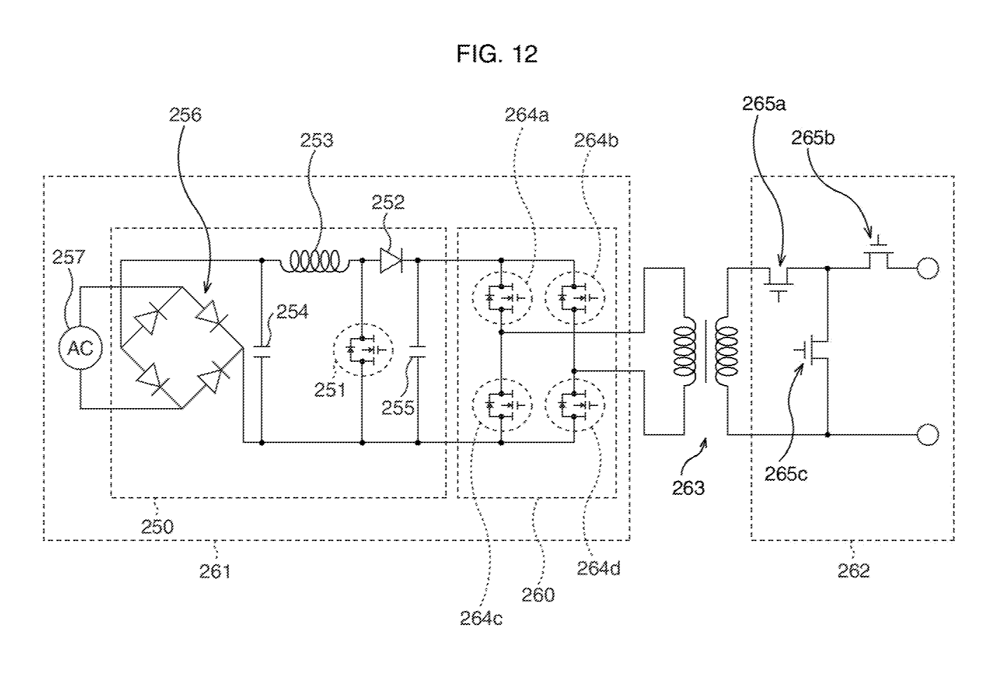

Next, a ninth embodiment will be explained. The ninth embodiment relates to a power supply apparatus equipped with a compound semiconductor device which includes a GaN-based HEMT. FIG. 12 is a wiring diagram illustrating the power supply apparatus according to the ninth embodiment.

The power supply apparatus includes a high-voltage, primary-side circuit 261, a low-voltage, secondary-side circuit 262, and a transformer 263 arranged between the primary-side circuit 261 and the secondary-side circuit 262.

The primary-side circuit 261 includes the PFC circuit 250 according to the eighth embodiment, and an inverter circuit, which may be a full-bridge inverter circuit 260, for example, connected between both terminals of the capacitor 255 in the PFC circuit 250. The full-bridge inverter circuit 260 includes a plurality of (four, in the embodiment) switching elements 264a, 264b, 264c and 264d.

The secondary-side circuit 262 includes a plurality of (three, in the embodiment) switching elements 265a, 265b and 265c.

In the embodiment, the compound semiconductor device according to any one of first to sixth embodiments is used for the switching element 251 of the PFC circuit 250, and for the switching elements 264a, 264b, 264c and 264d of the full-bridge inverter circuit 260. The PFC circuit 250 and the full-bridge inverter circuit 260 are components of the primary-side circuit 261. On the other hand, a silicon-based general MIS-FET (field effect transistor) is used for the switching elements 265a, 265b and 265c of the secondary-side circuit 262.

### Tenth Embodiment

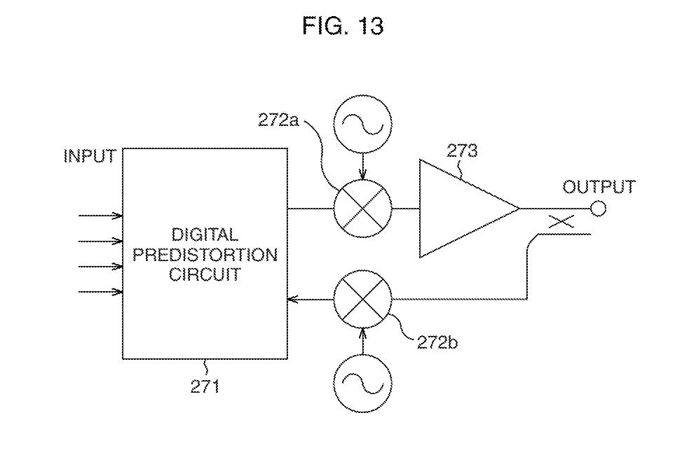

Next, a tenth embodiment will be explained. The tenth embodiment relates to a high-frequency amplifier equipped with the compound semiconductor device which includes a GaN-based HEMT. FIG. 13 is a wiring diagram illustrating the high-frequency amplifier according to the tenth embodiment.

The high-frequency amplifier includes a digital predistortion circuit 271, mixers 272a and 272b, and a power amplifier 273.

The digital predistortion circuit 271 compensates non-linear distortion in input signals. The mixer 272a mixes the input signal having the non-linear distortion already compensated, with an AC signal. The power amplifier 273 includes the compound semiconductor device according to any one of the first to tenth embodiments, and amplifies the input signal mixed with the AC signal. In the illustrated example of the embodiment, the signal on the output side may be mixed, upon switching, with an AC signal by the mixer 272b, and may be sent back to the digital predistortion circuit 271.

Composition of the compound semiconductor layers used for the compound semiconductor stacked structure is not specifically limited, and GaN, AlN, InN and so forth may be used. Also mixed crystals of them may be used.

Configurations of the gate electrode, the source electrode and the drain electrode are not limited to those in the above-described embodiments. For example, they may be configured by a single layer. The method of forming these electrodes is not limited to the lift-off process. The annealing after the formation of the source electrode and the drain electrode is omissible, so long the ohmic characteristic is obtainable. The gate electrode may be annealed.

In the embodiments, the substrate may be a silicon carbide (SiC) substrate, a sapphire substrate, a silicon substrate, a GaN substrate, a GaAs substrate or the like. The substrate may be any of electro-conductive, semi-insulating, and insulating ones. The thickness and material of each of these layers are not limited to those in the above-described embodiments.

According to the compound semiconductor devices and so forth described above, a leakage current can be suppressed while achieving normally-off operation, with the presence of the recombination center barrier layer.

All examples and conditional language provided herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A compound semiconductor device, comprising:
a substrate;
an electron transport layer and an electron supply layer formed over the substrate;
a gate electrode, a source electrode and a drain electrode formed over the electron supply layer;
a p-type semiconductor layer formed between the electron supply layer and the gate electrode; and
a hole canceling layer formed between the electron supply layer and the p-type semiconductor layer, the hole canceling layer containing a donor or a recombination center and canceling a hole.

2. The compound semiconductor device according to claim 1, wherein the p-type semiconductor layer is a GaN layer which contains Mg.

3. The compound semiconductor device according to claim 1, wherein the hole canceling layer contains a p-type impurity.

4. The compound semiconductor device according to claim 3, wherein the hole canceling layer contains Mg as the p-type impurity.

5. The compound semiconductor device according to claim 1, wherein the hole canceling layer contains Si as the donor.

6. The compound semiconductor device according to claim 1, wherein the hole canceling layer contains at least one selected from the group Fe, Cr, Co, Ni, Ti, V, and Sc as the recombination center.

7. The compound semiconductor device according to claim 1, further comprising a hole barrier layer formed between the electron supply layer and the p-type semiconductor layer, a band gap of the hole barrier layer being larger than that of the electron supply layer.

8. The compound semiconductor device according to claim 7, wherein composition of the electron supply layer is represented by AlₓGa₁₋ₓN (0<x<1), and
composition of the hole barrier layer is represented by Al_{y}Ga_{1-y}N (x<y<1).

9. The compound semiconductor device according to claim 7, wherein
composition of the electron supply layer is represented by AlₓGa₁₋ₓN (0<x<1), and
composition of the hole barrier layer is represented by In_{z}Ai_{1-z}N (0≦z≦1).

10. The compound semiconductor device according to claim 1, further comprising a gate insulating film formed between the gate electrode and the p-type semiconductor layer.

11. The compound semiconductor device according to claim 1, further comprising a termination film that covers the electron supply layer in each of a region between the gate electrode and the source electrode and a region between the gate electrode and the drain electrode.

12. A power supply apparatus, comprising
a compound semiconductor device, which comprises:
a substrate;
an electron transport layer and an electron supply layer formed over the substrate;
a gate electrode, a source electrode and a drain electrode formed over the electron supply layer;
a p-type semiconductor layer formed between the electron supply layer and the gate electrode; and
a hole canceling layer formed between the electron supply layer and the p-type semiconductor layer, the hole canceling layer containing a donor or a recombination center, and canceling a hole.

13. An amplifier, comprising
a compound semiconductor device, which comprises:
a substrate;
an electron transport layer and an electron supply layer formed over the substrate;
a gate electrode, a source electrode and a drain electrode formed over the electron supply layer;
a p-type semiconductor layer formed between the electron supply layer and the gate electrode; and
a hole canceling layer formed between the electron supply layer and the p-type semiconductor layer, the hole canceling layer containing a donor or a recombination center, and canceling a hole.

14. A method of manufacturing a compound semiconductor device, comprising:
forming an electron transport layer and an electron supply layer over a substrate;
forming a gate electrode, a source electrode and a drain electrode over the electron supply layer;
forming a p-type semiconductor layer which is located between the electron supply layer and the gate electrode, before the forming the gate electrode; and
forming a hole canceling layer which is located between the electron supply layer and the p-type semiconductor layer, before the forming the p-type semiconductor layer, the hole canceling layer containing a donor or a recombination center and canceling a hole.

15. The method of manufacturing a compound semiconductor device according to claim 14, wherein the p-type semiconductor layer is a GaN layer which contains Mg.

16. The method of manufacturing a compound semiconductor device according to claim 14, wherein the hole canceling layer contains a p-type impurity.

17. The method of manufacturing a compound semiconductor device according to claim 16, wherein the hole canceling layer contains Mg as the p-type impurity.

18. The method of manufacturing a compound semiconductor device according to claim 14, wherein the hole canceling layer contains Si as the donor.

19. The method of manufacturing a compound semiconductor device according to claim 14, wherein the hole canceling layer contains at least one selected from the group Fe, Cr, Co, Ni, Ti, V, and Sc as the recombination center.

20. The method of manufacturing a compound semiconductor device according to claim 14, further comprising forming a hole barrier layer which is located between the electron supply layer and the hole canceling layer, before the forming the hole canceling layer, a band gap of the hole barrier layer being larger than that of the electron supply layer.
